(19) United States
(12) Patent Application Publication
(10) Pub. No.: US 2026/0293080 A1
(43) Pub. Date: Sep. 24, 2026

(54) STACKED THREE-TRANSISTORS MEMORY CELLS, COMPUTE-IN-MEMORY INTEGRATED CIRCUITS, AND COMPUTING DEVICES

(71) Applicant: Purdue Research Foundation, West Lafayette, IN (US)

(72) Inventors: Zheng Sun, Lafayette, IN (US); Hao-Yu Lan, West Lafayette, IN (US); Luqi Zheng, West Lafayette, IN (US)

(21) Appl. No.: 19/300,297

(22) Filed: Aug. 14, 2025

Related U.S. Application Data
(60) Provisional application No. 63/683,377, filed on Aug. 15, 2024.

(51) Int. Cl. H10B 12/00; G11C 11/4091; G11C 11/4094; G11C 11/4096; H10W 20/41; H10W 20/42

(52) U.S. Cl. CPC H10B 12/00; G11C 11/4091; G11C 11/4094; G11C 11/4096; H10W 20/422; H10W 20/435

(57) ABSTRACT

Three-dimensional three-transistors (3T) memory cells having three thin film transistors and a capacitor that are stacked on top of each other in a three-dimensional configuration. An array of a plurality of the three-transistors memory cell can be used to form a memory array. The three-transistors memory cell can be implemented in an integrated circuit as a top-end-of-line layer disposed on top of the back-end-of-line layer of the integrated circuit. Such an integrated circuit may be configured to form an embedded dynamic random-access memory (eDRAM) compute-in-memory integrated circuit. The eDRAM compute-in-memory may be used in a computing device. The computing device may be configured for executing an artificial intelligence neural network where the nodes of the neural network map directly to the array of stacked 3T memory cells in the (eDRAM) compute-in-memory.

### CROSS-REFERENCE TO RELATED APPLICATIONS

This application claims the benefit of provisional U.S. Patent Application No. 63/683,377 filed Aug. 15, 2024, the contents of which are incorporated herein by reference.

### BACKGROUND OF THE INVENTION

The invention generally relates to digital memory integrated circuits (also referred to herein as “chips” or “cells”). The invention particularly relates to stacked three-dimensional three-transistors memory cells that are based on stacked thin-film transistors, as well as components, products, and methods related thereto.

As the use and reliance on computer technology continue to increase across all aspects of life, there is constant pressure to minimize size and increase computing power density of digital computers. One area for this space savings can be found in the digital memory used by computing systems. Memory cells that use thin film transistors (TFTs) are one such space-saving design widely used in modern integrated circuit memory devices.

U.S. Patent Publication No. 2023/0171936 to Sharma et al. (hereinafter, Sharma et al. '936) discloses a two transistor (2T) memory cell that uses TFTs as access and gain transistors that are provided in different layers above a substrate, enabling a stacked architecture. The 2T memory cell includes an access TFT provided in a first layer over the substrate, and a gain TFT provided in a second layer over the substrate, such that the first layer is between the substrate and the second layer. The contents of U.S. Patent Publication No. 2023/0171936 (Sharma et al. '936) are incorporated herein by reference.

U.S. Pat. No. 11,450,669 to Sharma et al. (hereinafter, Sharma et al. '669) discloses a stacked thin-film transistor based embedded dynamic random-access memory (eDRAM). An IC device with arrays of eDRAM cells use TFTs as selector transistors that form a stacked TFT based eDRAM memory array. The stacked TFT based eDRAM has memory cells provided in a first layer over a substrate and memory cells provided in a second layer above the first layer. The memory cells in both the first and second layers use TFTs as selector transistors. The contents of U.S. Pat. No. 11,450,669 (Sharma et al. '669) are incorporated herein by reference.

U.S. Pat. No. 11,462,541 to Vinasco et al. discloses memory cells based on vertical thin-film transistors. A semiconductor device has a memory cell including a transistor and a capacitor disposed above a horizontal substrate. The transistor gate electrode and a channel layer are oriented vertically. The channel layer is around the gate electrode and separated from the gate electrode by a gate dielectric layer. The capacitor is within an inter-level dielectric layer above the substrate and has a first plate coupled with a second portion of the channel layer of the transistor and a second plate separated from the first plate by a capacitor dielectric layer. The first plate of the capacitor is also a source electrode of the transistor. The contents of U.S. Pat. No. 11,462,541 (Vinasco et al.) are incorporated herein by reference.

U.S. Pat. No. 11,758,711 to Wang et al. (hereinafter, Wang et al.) discloses a thin-film transistor embedded dynamic random-access memory with a shallow bitline. The eDRAM memory array has a memory cell that uses a TFT as a selector transistor. One source/drain (S/D) electrode of the TFT is coupled to a capacitor for storing a memory state of the cell, while the other S/D electrode is coupled to a shallow bitline. The shallow bitline has a thickness that is less than a thickness of the metal interconnect provided in the same metal layer as the bitline used for providing electrical connectivity for components outside of the memory array. The memory cells may be formed in a back end of line (BEOL) process. The contents of U.S. Pat. No. 11,758,711 (Wang et al.) are incorporated herein by reference.

A limitation of these two-transistor or one-transistor memory cell designs is that they are not well suited for application to robust multiply and accumulate (MAC) operations. Therefore, it would be desirable to have a memory cell that can be applied to provide improved robust MAC operations, and preferably in less space than two-transistor or one-transistor memory cell designs.

### BRIEF SUMMARY OF THE INVENTION

The intent of this section of the specification is to briefly indicate the nature and substance of the invention, as opposed to an exhaustive statement of all subject matter and aspects of the invention. Therefore, while this section identifies subject matter recited in the claims, additional subject matter and aspects relating to the invention are set forth in other sections of the specification, particularly the detailed description, as well as any drawings.

The present invention provides, but is not limited to, stacked three-transistors (3T) memory cells, compute-in-memory integrated circuits, embedded dynamic random-access memory (eDRAM) compute-in-memory devices, and computing devices.

According to a nonlimiting aspect, a stacked three-transistors (3T) memory cell includes a first thin-film-transistor (TFT), a second TFT, and a third TFT. The first TFT, second TFT, and third TFT are stacked in a plurality of layers in a three-dimensional (3D) configuration.

According to another nonlimiting aspect, a compute-in-memory integrated circuit includes a front-end-of-line (FEOL) layer having one or more logic circuits, a back-end-of-line (BEOL) layer disposed on top of a top layer of the FEOL layer, and a top-end-of-line (TOEL) layer disposed on a top layer of the BEOL layer. The TOEL layer includes one or more stacked 3T memory cells operatively coupled with the top layer of the BEOL layer to form an electrical circuit therewith. One or more of the one or more stacked 3T memory cells includes a first TFT, a second TFT, a third TFT, and a capacitor stacked in a plurality of layers in a 3D configuration. In some embodiments, the CIM integrated circuit may form or otherwise form part of an embedded dynamic random-access memory (eDRAM) circuit.

According to yet another nonlimiting aspect, an eDRAM compute-in-memory device includes an array of a plurality of the stacked 3T memory cells described above. Each stacked 3T memory cell has a storage node that is in communication with one input signal and isolated from all other input signals in the memory array.

According to still another nonlimiting aspect, a computing device includes the eDRAM compute-in-memory device described above.

Technical aspects of stacked 3T memory cells as described above preferably include the ability to provide more robust MAC operations and/or provide a more robust memory array in less space than conventional eDRAM configurations.

These and other aspects, arrangements, features, and/or technical effects will become apparent upon detailed inspection of the figures and the following description.

### BRIEF DESCRIPTION OF THE DRAWINGS

FIG. 1 is a schematic illustration of a cross-sectional view of an example integrated circuit (IC) device according to some embodiments of the present disclosure.

FIG. 2 is a schematic illustration of an example configuration of a three-transistor (3T) memory cell with three stacked thin-film transistors (TFTs) and one capacitor, according to some embodiments of the present disclosure.

FIG. 3 is a schematic illustration of an example configuration of a memory array implementing a plurality of 3T memory cells having three stacked TFTs corresponding to the structure in FIG. 2, according to some embodiments of the present disclosure.

FIG. 4 is a schematic illustration of another example configuration of a 3T memory cell with three stacked TFTs and one capacitor, according to some embodiments of the present disclosure.

FIG. 5 is a schematic illustration of an example configuration of a memory array implementing a plurality of 3T memory cells having three stacked TFTs corresponding to the structure in FIG. 4, according to some embodiments of the present disclosure.

FIG. 6 is a block diagram of a 3T eDRAM compute-in-memory chip according to some embodiments of the present disclosure.

FIG. 7 is a cross-sectional view in the y-z plane of the IC device of FIG. 1 implemented with the 3T memory cell of FIG. 2.

FIG. 8 is a cross-sectional view in the y-z plane of the IC device of FIG. 1 implemented with the 3T memory cell of FIG. 4.

FIG. 9 is a top view of an integrated circuit wafer manufactured with appropriate dies to form one or more memory arrays implementing the 3T memory cells, in accordance with any of the embodiments disclosed herein.

FIG. 10 is a block diagram of a nonlimiting example computing device that may include one or more of the memory arrays implementing the 3T memory cells.

FIG. 11 schematically represents a fully connected layer of neural network with n inputs and m neurons mapped to the memory array in a 3T eDRAM compute-in-memory chip of the present disclosure.

### DETAILED DESCRIPTION OF THE INVENTION

The intended purpose of the following detailed description of the invention and the phraseology and terminology employed therein is to describe what is shown in the drawings, which include the depiction of and/or relate to one or more nonlimiting embodiments of the invention, and to describe certain but not all aspects of what is depicted in the drawings, including the embodiment(s) to which the drawings relate. The following detailed description also identifies certain but not all alternatives of the embodiment(s). As nonlimiting examples, the invention encompasses additional or alternative embodiments in which one or more features or aspects shown and/or described as part of a particular embodiment could be eliminated, and also encompasses additional or alternative embodiments that combine two or more features or aspects shown and/or described as part of different embodiments. Therefore, the appended claims, and not the detailed description, are intended to recite what at least provisionally are believed to be aspects of the invention, including certain but not necessarily all of the aspects and alternatives described in the detailed description.

To facilitate the description provided below of the embodiment(s) represented in the drawings, relative terms, including but not limited to, “proximal,” “distal,” “anterior,” “posterior,” “vertical,” “horizontal,” “lateral,” “front,” “rear,” “side,” “forward,” “rearward,” “top,” “bottom,” “upper,” “lower,” “above,” “below,” “right,” “left,” etc., may be used in reference to the orientation of the chips and various components thereof during its use and/or as represented in the drawings. All such relative terms are useful to describe the illustrated embodiment(s) but should not be otherwise interpreted as limiting the scope of the invention.

As used herein the terms “a” and “an” to introduce a feature are used as open-ended, inclusive terms to refer to at least one, or one or more of the features, and are not limited to only one such feature unless otherwise expressly indicated. Similarly, use of the term “the” in reference to a feature previously introduced using the term “a” or “an” does not thereafter limit the feature to only a single instance of such feature unless otherwise expressly indicated.

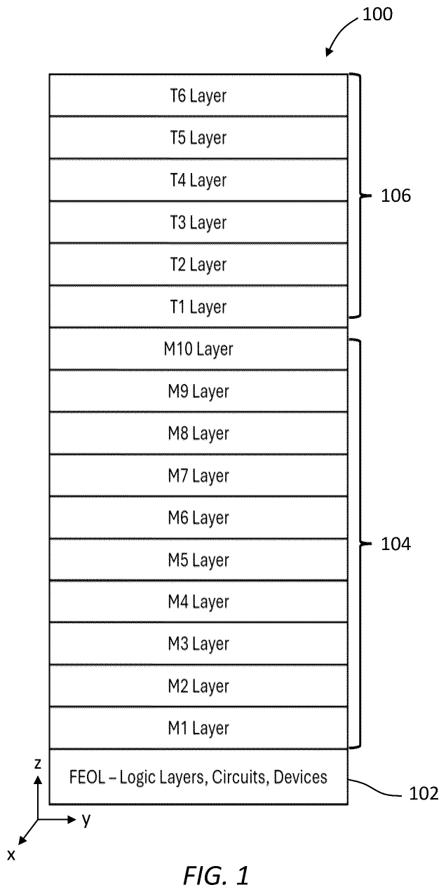

FIGS. 1 through 11 represent various aspects of compute-in-memory integrated (CIM) circuits (“chips”) built in a three-dimensional (3D) architecture. The CIM chips include 3D three-transistors memory cells that are based on stacked thin-film transistors (TFT). These CIM chips are preferably capable of having a smaller chip design area than conventional CIM chips built in a planar architecture while providing the same or similar performance capabilities. These CIM chips may also make it possible to increase memory cell density within a given footprint area over conventional CIM chips built in a planar architecture. Additional features, functions, and benefits will be apparent from the following detailed description and the attached drawings.

In some nonlimiting aspects of the invention, a 3-transistors (3T) memory cell may have a stacked TFT-based 3T memory cell design. This design preferably allows for increased memory cell density within a given footprint area, or alternatively, reduces the footprint area of a memory array while maintaining the same memory cell density. When one, or two, or three transistors of a 3T memory cell are implemented as thin-film transistors (TFTs), these transistors can be placed in different layers above a substrate, thereby forming a 3D architecture.

A 3T memory cell implementing some nonlimiting aspects of the invention may include a write access TFT provided in a first layer over a substrate, and a storage TFT along with a read access TFT in a second layer over the substrate. The first layer is situated between the substrate and the second layer. In this arrangement, the storage and read access TFTs can be said to be stacked above the write access TFT.

The three transistors memory cell can be used for 3T embedded dynamic random-access memory compute-in-memory (CIM) macro. In such a usage, the three transistors memory cell can be configured to provide parallel binary multiply and accumulate (MAC) operations and/or to provide in-memory multiplication and accumulation. Such MAC operations are at the core of computing-in-memory. Thus, the 3T memory cell can provide more robust MAC operation for computing-in-memory tests in long retention time.

Two-transistor or one-transistor memory cell designs are not well suited to be applied to robust MAC operations because the storage nodes cannot be distributed by input signal. In contrast, the stacked 3TFT memory cell configuration in some nonlimiting embodiments of the present invention can provide parallel binary multiply and accumulate (MAC) operations. The stacked 3TFT memory cell configuration may also include in-memory MAC operations, which are at the core of computing-in-memory. In some configurations, the stacked 3TFT memory cell configuration can be connected to only a single input signal line so as to isolate the storage node from other input signal lines and thereby provide more robust MAC operation for computing-in-memory test in long retention time. Thus, the stacked 3TFT memory cell configuration of the present disclosure can provide more robust MAC operations than the 1T- or 2T memory cell configurations.

Turning now to FIG. 1, an integrated circuit (IC) device 100 is represented as including a front end of line (FEOL) layer 102, a back-end-of-line (BEOL) layer 104, and a top-end-of-line (TEOL) layer 106. The BEOL layer 104 is stacked on top of the FEOL layer 102, and the TEOL layer 106 is stacked on top of the BEOL layer 104. Thus, the middle BEOL layer 104 is sandwiched between the lower FEOL layer 102 and the upper TEOL layer 106. Unlike a two transistor (2T) memory cell that uses TFTs as access and gain transistors, the stacked TFT-based 3T memory cell of FIG. 1 provides the TEOL layer 106 on top of the BEOL layer 104 of the integrated circuit device 100. In the process of manufacturing IC chips, the TEOL layer 106 may be added as another extra layer on top of the original chip (the FEOL layer 102 and BEOL layer 104) after the fabrication of the original chip and therefore may not belong to the original chip.

The FEOL layer 102 includes most of the various logic layers, circuits, and devices to drive and control a logic IC. As understood in the art, FEOL layer semiconductor processing and structures generally refer to a first portion of IC fabrication where individual devices (e.g., transistors, capacitors, resistors, etc.) are patterned in a semiconductor substrate or layer. The FEOL layer 102 generally includes everything up to (but not including) the deposition of metal interconnect layers. As an example, a transistor formed in the FEOL layer 102 may also be referred to as a front-end transistor. Following the last FEOL operation, the result is typically a wafer with isolated transistors (e.g., without any wires) and/or other individual devices. The FEOL layer 102 may include any desired configuration for providing any given functionalities as understood in the art either currently or in the future and is not further elaborated upon herein. Additional exemplary information relative to possible configurations of the FEOL layer 102 may be found in one or more of Sharma et al. '936, Sharma et al. '669, Vinasco et al., and Wang et al.

The BEOL layer 104 is configured for computing logic processes. In the nonlimiting example of FIG. 1, the BEOL layer 104 includes ten metal interconnect layers: metal 1 layer (M1), metal 2 layer (M2), metal 3 layer (M3), metal 4 layer (M4), metal 5 layer (M5), metal 6 layer (M6), metal 7 layer (M7), metal 8 layer (M8), metal 9 layer (M9), and metal 10 layer (M10). Although ten metal interconnect layers are shown in the nonlimiting example of FIG. 1, in other embodiments, the IC device 100 may include any other number of two or more of such metal interconnect layers. Various ones of the metal layers (e.g., M1-M10) of the BEOL layer 104 may be used to interconnect the various inputs and outputs of the FEOL layer 102, and/or may be used to house different TFT based eDRAM cells. Any one or more of the metal layers (e.g., M1-M10) of the BEOL layer 120 may include a via portion and a trench/interconnect portion. The trench portion of a metal layer may be above or below a via portion of any given metal layer of the BEOL layer 104. The trench portion may be configured for transferring signals and power along metal lines (also sometimes referred to as “trenches”) extending in the x-y plane (e.g., in the x or y directions), while the via portion of a metal layer is configured for transferring signals and power through metal vias extending in the z-direction (vertical as shown in FIG. 1), e.g., to any of the adjacent metal layers above or below. Accordingly, vias connect metal structures (e.g., metal lines or vias) from one metal layer to metal structures of an adjacent metal layer. While referred to as “metal” layers, various layers of the BEOL layer 104 (e.g., M1-M10) may include only certain patterns of conductive metals, e.g., copper (Cu) or aluminum (Al), or metal alloys, or more generally, patterns of any suitable electrically conductive material, formed in an insulating medium such as interlayer dielectric (ILD). The insulating medium may include any suitable ILD materials such as silicon oxide, silicon nitride, aluminum oxide, and/or silicon oxynitride. Additional exemplary information relative to possible configurations of the BEOL layer 104 may be found in one or more of Sharma et al. '936, Sharma et al. '669, Vinasco et al., and Wang et al.

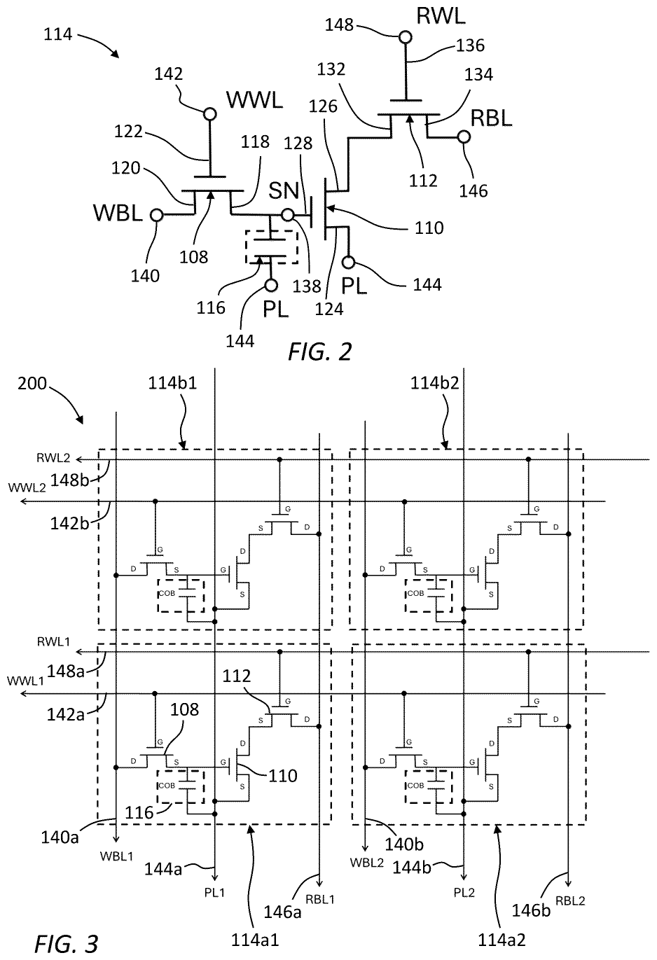

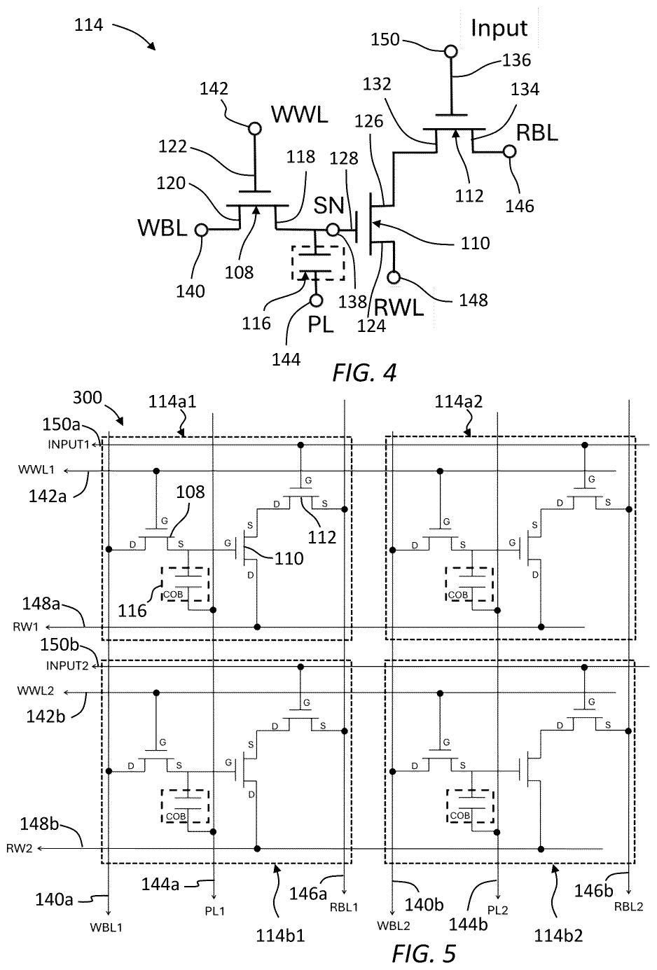

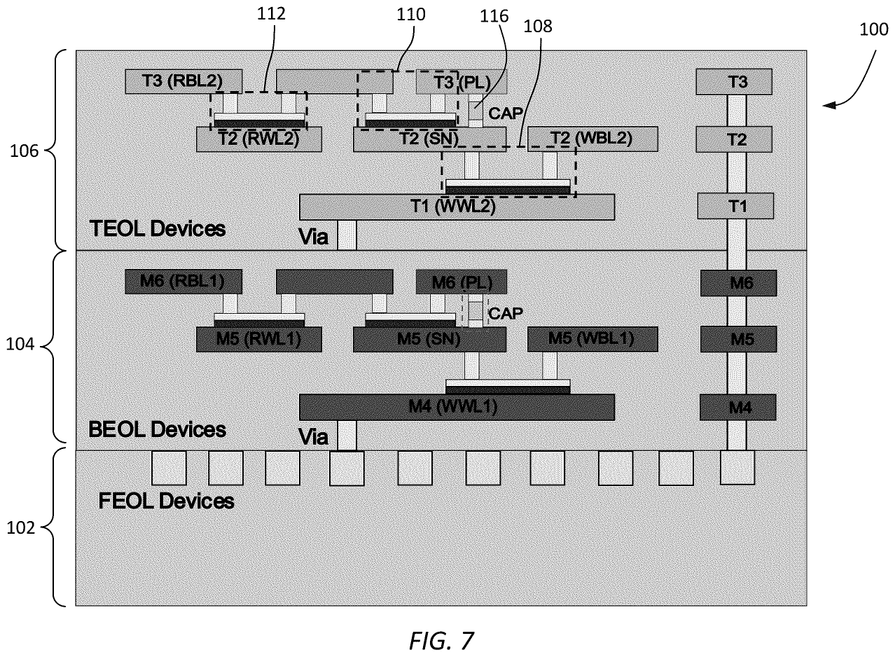

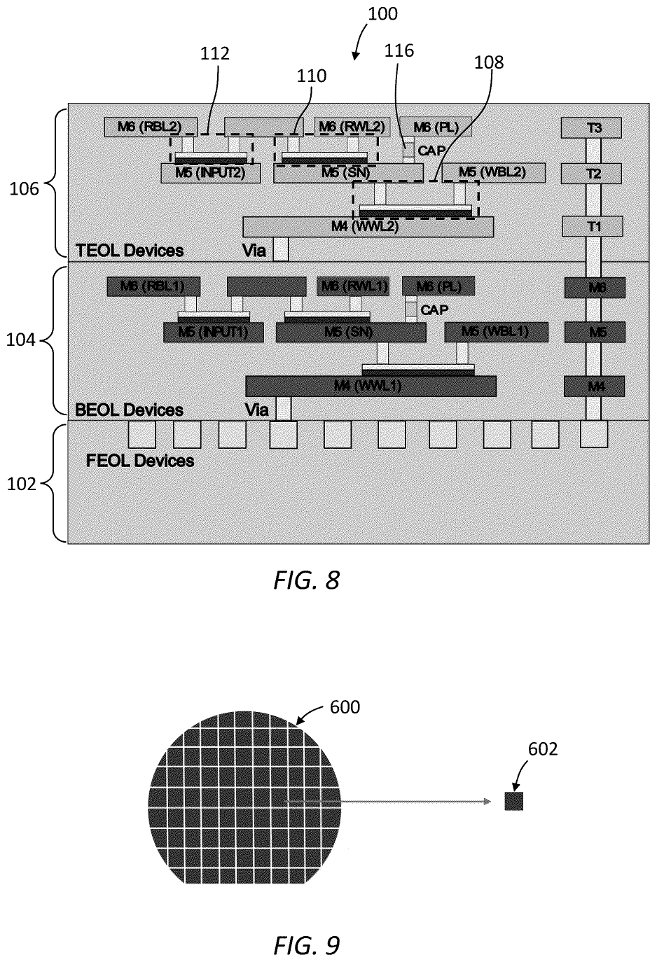

The TEOL layer 106 is disposed on top of the BEOL layer 104. The TEOL layer 106 is represented in FIG. 1 as including six TFT layers T1, T2, T3, T4, T5, and T6 stacked on top of each other, which together enable three stacked thin-film transistors (TFTs) 108, 110, and 112 to be formed and stacked vertically (in the Z-direction) on top of each other, as nonlimiting examples, as represented in FIGS. 7 and 8. The three transistors 108, 110, and 112 together form at least one 3T memory cell 114 (e.g., FIG. 2 or 4) according to certain aspects of the present disclosure.

As seen in FIG. 2, the 3T memory cell 114 includes the three thin-film transistors 108, 110, and 112. The 3T memory cell preferably also includes a capacitor 116. The first transistor 108 includes a first S/D electrode 118, a second S/D electrode 120, and a gate electrode 122. The second transistor 110 includes a first S/D electrode 124, a second S/D electrode 126, and a gate electrode 128. The third transistor 112 includes a first S/D electrode 130, a second S/D electrode 132, and a gate electrode 134. The first S/D electrode 118 of the first transistor 108 is coupled to the gate electrode 128 of the second transistor 110 via a storage node 138. The second S/D electrode 120 of the first transistor 108 is coupled to a write bitline (WBL) 140. The gate electrode 122 of the first transistor 210 is coupled to a write wordline (WWL) 142. The first S/D electrode 124 of the second transistor 110 is coupled to a capacitor plate line (PL) 144. The second S/D electrode 126 of the second transistor 110 is coupled to the first S/D electrode 132 of the third transistor 112. The second electrode 134 of the third transistor 112 is connected to a read bitline (RBL) 146. The gate electrode 136 of the third transistor 112 is connected to a read wordline (RWL) 148. A memory state, or a bit value (i.e. logical “1” or “0”) of the memory cell 114 may be represented by charge indicative of the bit value, stored in the parasitic capacitance of the storage node 138 between (i.e., coupled to) the gate electrode 128 of the second transistor 110 and the first S/D electrode 118 of the first transistor 108. The capacitor 116 may be used for storing charge representative of the bit value. For example, in some embodiments, the capacitor 116 may be used as a storage node instead of, or in addition to, the storage node 138, where the capacitance on the capacitor 116 is indicative of the memory state of the memory cell 114. The capacitor 116 may have a first capacitor electrode coupled to the first electrode 118 of the first transistor 108 and/or to the storage node 230, and a second capacitor electrode coupled to the capacitor plate line (PL) 144. In some embodiments, the capacitor 116 may be fabricated to have a three-dimensional metal-insulator-metal (MIM) structure or a metal-oxide-metal (MOM) structure. As understood in the art, source and drain terminals are interchangeable in transistors, and the notation “S/D” terminals is sometimes used to indicate the interchangeability of the source(S) and drain (D) terminals. Therefore, while some examples and illustrations may be presented here with reference to the first S/D electrodes 118, 124, and 132 as being source terminals, and the second S/D electrodes 120, 126, and 134 as being drain terminals, in other embodiments, any of S/D terminals of the transistors 108, 110, and 112 may be reversed. In some embodiments, the first transistor 108 may be considered an access transistor, and the second transistor 110 may be considered a gain transistor. The embodiment of the memory cell 114 shown in FIG. 2 is shown configured and implemented as part of a memory array 200 shown in FIG. 3.

Turning now to FIG. 3, the memory array 200 is a rectangular array of any desired size. In this example, the memory array 200 is shown with four of the memory cells 114, designated here as 114a1, 114a2, 114b1, and 114b2, arranged in a rectangular array of rows (e.g., a, b, etc.) and columns (e.g., 1, 2, etc.), but any number of the memory cells 114 could be implemented by simply extending the memory array 200 as well understood in the art. The memory cells 114a1 and 114a2 form a first row, the memory cells 114b1 and 114b2 form a second row, the memory cells 114a1 and 114b1 form a first column, and the memory cells 114b1 and 114b2 may be seen as forming a second column. The transistors 108, 110, and 112 and the capacitor 116 are labeled for the memory cell 114al only, it being understood that the remaining memory cells 114a2, 114b1, and 114b2 are substantially identical. For the remaining memory cells, example designations of transistor terminals are only shown with labels “S” (source terminal), “D” (drain terminal), and “G” (gate terminal), and the optional capacitor 116 is shown with a label “COB.” The same terminals of different memory cells in a given row may be coupled to the same respective line, and the same terminals of different memory cells in a given column may be coupled to the same respective line. For example, the gate terminals 122 of the second transistors 108 of the memory cells 114a1 and 114a2 of the first row are coupled to a common first write wordline (WWL1) 142a, which may then be coupled to a first WWL driver, and the gate terminals of the first transistors 108 of the memory cells 114b1 and 114b2 of the second row are coupled to a common second write wordline (WWL2) 142g, which may then be coupled to a second WWL driver. In a generally similar fashion, the remaining connections 140, 144, 146, and 148 of the memory cells 114a1, 114a2, 114b1, and 114b2 are made to corresponding common lines WBL1 140a or WBL2 140b, PL1 144a or PL2 144b, RBL1 146a or RBL2 146b, and RWL1 148a or RWL2 148b, as appropriate and shown in FIG. 3. Thus, for example, the connections 140, 142, 144, 146, and 148 of memory cell 114al are with lines WBL1, WWL1, PL1, RBL1, and RWL1, respectively; the connections 140, 142, 144, 146, and 148 of memory cell 114a2 are with lines WBL2, WWL1, PL2, RBL2, and RWL1, respectively; the connections 140, 142, 144, 146, and 148 of memory cell 114b1 are with lines WBL1, WWL2, PL1, RBL1, and RWL2, respectively; and the connections 140, 142, 144, 146, and 148 of memory cell 114b2 are with lines WBL2, WWL2, PL2, RBL2, and RWL2, respectively. Each of the lines RWL1, RWL2, WWL1, WWL2, WBL1, WBL2, PL1, PL2, RBL1, and RBL2 is connected to its own respective driver, such as RWL driver 1, RWL driver 2, WWL driver 1, WWL driver 2, WBL driver 1, WBL driver 2, PL voltage generator 1, PL voltage generator 2, RBL driver 1, and RBL driver 2.

In the embodiment shown in FIG. 4, the three transistors 108, 110, and 112 and the capacitor 116 of the memory cell 114 are configured the same as described in reference to the embodiment in FIG. 2, and reference is made to the descriptions thereof. In this embodiment, however, the memory cell 114 is configured for and implemented into a slightly different memory array 300 configuration as shown in FIG. 5. Thus, in this embodiment, the first electrode 124 of the second transistor is connected to the read wordline (RWL) 148 (instead of the PL 144), and the gate electrode 136 of the third transistor 112 is coupled to an input line 150. The remaining connections 140, 142, 144, and 146 are also the same as described in FIG. 2.

As seen in FIG. 5, the memory array 300 is a rectangular array similar to the memory array 200 of FIG. 3, except that each row has an input line (e.g., INPUT1 and INPUT2), write wordline line (e.g., WWL1 and WWL2), and a read wordline (e.g., RWL1 and RWL2), and each column has a write bitline (e.g., WBL1 and WBL2), a capacitor plate line (e.g., PL1 and PL2), and a read bitline (e.g., RBL1 and RBL2). In the rectangular array, the memory cells 114al and 114a2 are in a first row connected to common lines INPUT1 150a, WWL1 142a, and RW1 148a; the memory cells 114b1 and 114b2 are in a second row connected to common lines INPUT2 150b, WWL2 142b, and RW2 148b; the memory cells 114a1 and 114b1 are in a first column connected to common lines WBL1 140a, PL1 144a, and RBL1 146a; and the memory cells 114a2 and 114b2 are in a second column connected to common lines WBL2 140b, PL2 144b, and RBL2 146b. Thus for example, the connections 140, 142, 144, 146, 148, and 150 of memory cell 114al are with lines WBL1, WWL1, PL1, RBL1, RWL1, and INPUT 1, respectively; the connections 140, 142, 144, 146, 148, and 150 of memory cell 114a2 are with lines WBL2, WWL1, PL2, RBL2, RWL1, and INPUT 1, respectively; the connections 140, 142, 144, 146, 148, and 150 of memory cell 114b1 are with lines WBL1, WWL2, PL1, RBL1, RWL2, and INPUT 2, respectively; and the connections 140, 142, 144, 146, 148, and 150 of memory cell 114b2 are with lines WBL2, WWL2, PL2, RBL2, RWL2, and INPUT 2, respectively. Each of the lines RWL1, RWL2, WWL1, WWL2, WBL1, WBL2, PL1, PL2, RBL1, RBL2, INPUT1, and INPUT2 is connected to its own respective driver RWL driver 1, RWL driver 2, WWL driver 1, WWL driver 2, WBL driver 1, WBL driver 2, PL voltage generator 1, PL voltage generator 2, RBL driver 1, RBL driver 2, INPUT driver 1, and INPUT driver 2.

Although each of the memory arrays 200 and 300 is shown as a rectangular array, it is understood that the memory arrays are not limited to rectangular arrays, but that other configurations for the memory arrays are also possible. Additional exemplary information relative to possible configurations of the memory arrays 200 and 300 may be found in any one or more of Sharma et al. '936, Sharma et al. '669, Vinasco et al., and Wang et al.

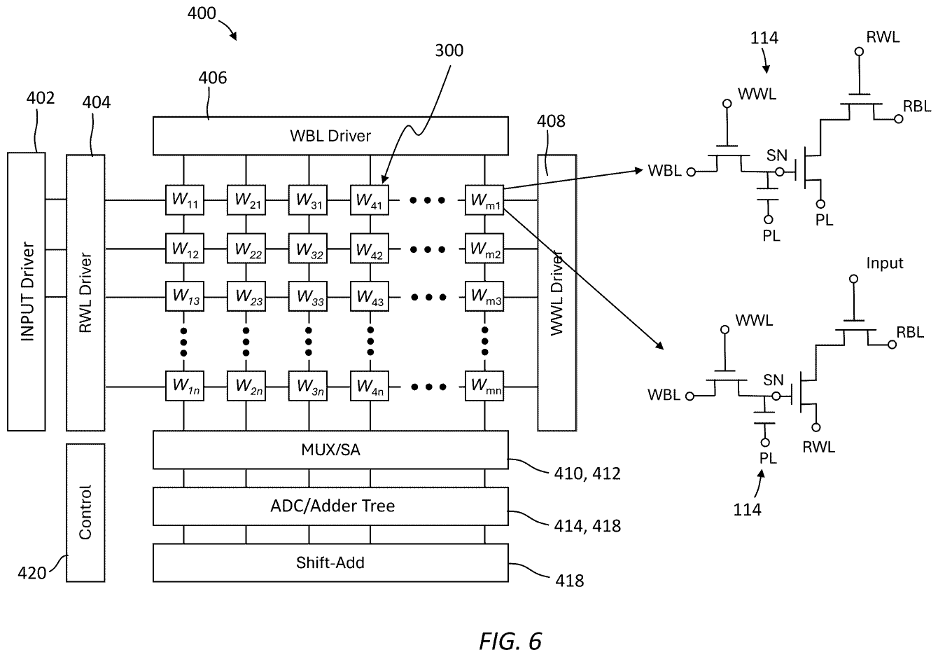

FIG. 6 shows an example overall architecture of a 3T eDRAM compute-in-memory (CIM) device 400 that incorporates the 3T eDRAM memory array 300 with m columns and n rows of the 3T memory cells 114. In this embodiment, the 3T eDRAM CIM device 400 is implemented in the form of an integrated circuit chip and is referred to hereinafter as a “chip”; however, the 3T eDRAM CIM device 400 could be implemented in other forms as well and is not necessarily limited to the integrated circuit chip form. The CIM chip 400 includes an input driver 402, a read writeline (RWL) driver 404, a write bitline (WBL) driver 406, a write writeline (WWL) driver 408, a multiplexer (MUX) 410, a sense amplifier (SA) 412, an analog-to-digital converter (ADC) 414, an adder tree 416, a shift-add unit 418, and a controller 420, operatively interconnected with each other and with the 3T eDRAM memory array 300 to provide for both data storage and computing functionality.

As seen in FIG. 7, the IC device 100 formed with the 3T memory cell 114 in the configuration of FIGS. 2 and 3 uses the three transistors 108, 110, and 112 formed in a plurality of the vertically stacked TFT layers in a 3D stacked configuration to form the memory cell 114. The first transistor 108 is disposed in a first layer (stacked) directly on top of the BEOL layer 104. The second transistor 110 is disposed in a second layer above the first layer. The second transistor 110 is stacked vertically directly on top of the first transistor 108. The third transistor 112 is on the same layer (the second layer) as the second transistor 110. The third transistor 112 may be offset laterally at least partly from the first transistor 108. The capacitor 116 is sandwiched in between the first transistor 108 and the second transistor 110. The BEOL layer 104 and FEOL layer 102 are configured to form the circuit layout of the memory array 200 in FIG. 3 with the appropriate connections to the memory cell 114 as previously described herein.

Appropriate vias connect the electrodes of the transistors 108, 110, and 112, and the capacitor 116 between adjacent layers of the TEOL layer 106 and with the top layer of the BEOL layer 104 in any suitable manner to affect the various circuits as disclosed herein or otherwise needed in any other desired manner. The capacitor 116 may be any type of capacitor suitable for use in a stacked integrated circuit, such as a metal-insulator-metal (MIM) capacitor or a metal-oxide-metal (MOM) capacitor.

As seen in FIG. 8 the IC device 100 formed with the 3T memory cell 114 in the configuration of FIGS. 4 and 5 also uses the three transistors 108, 110, and 112 in a 3D stacked configuration. The three transistors 108, 110, and 112 and the capacitor 116 are stacked on top of the BEOL layer 104 in the same manner as in FIG. 7. The BEOL layer 104 and FEOL layer 102 are configured to form the circuit layout of the memory array 300 in FIG. 5 with the appropriate connections to the memory cell 114 as previously described herein. Appropriate vias connect the electrodes of the transistors 108, 110, and 112, and the capacitor 116 between adjacent layers of the TEOL layer 106 and with the top layer of the BEOL layer 104 in any suitable manner to affect the various circuits as disclosed herein or otherwise needed in any other desired manner. The capacitor 116 may be any type of capacitor suitable for use in a stacked integrated circuit, such as a metal-insulator-metal (MIM) capacitor or a metal-oxide-metal (MOM) capacitor.

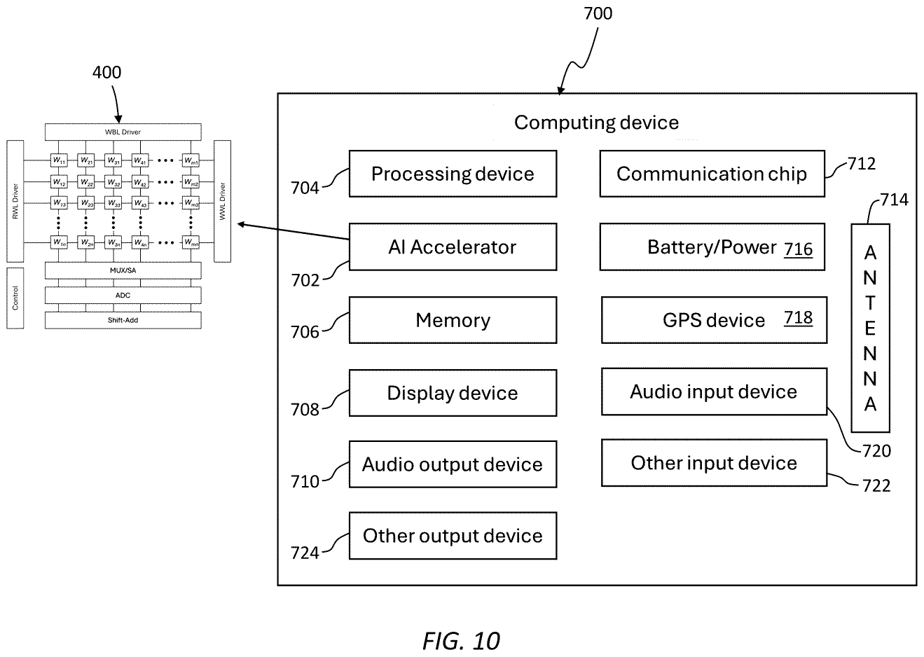

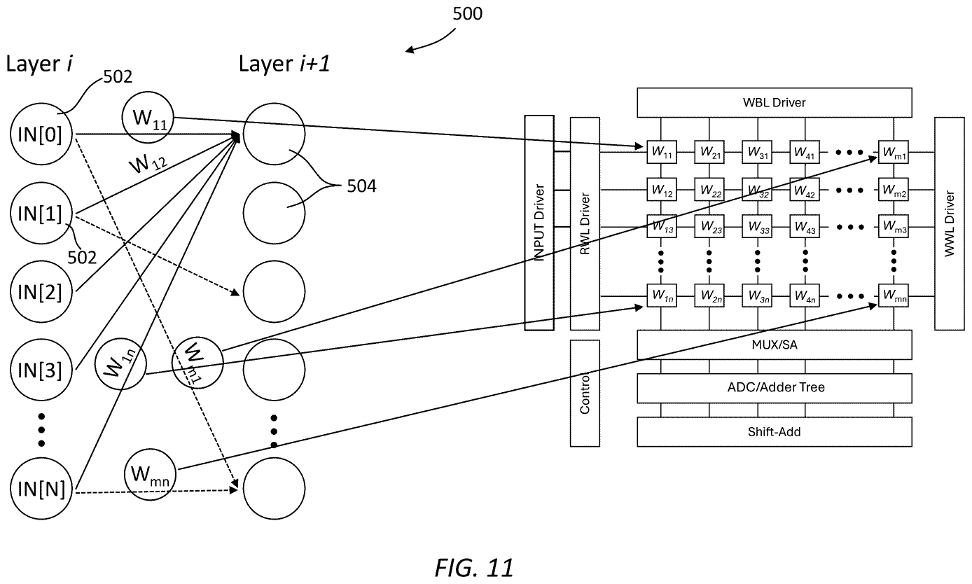

As seen in FIG. 9, the memory cells 114 and/or memory arrays 200 and/or 300 may be formed as a wafer 600 with appropriate dies 602 in any manner suitable for such fabrication. The wafer 600 is manufactured to form one or more memory arrays (e.g., 200 or 300) implementing the 3T memory cells 114 with stacked transistors 108, 110, and 112. Turning to FIG. 10, a computing device 700 includes one or more memory arrays (e.g., 200 and/or 300) having the 3T memory cells 114 with three stacked TFTs in a 3D stacked configuration in accordance with any of the embodiments disclosed herein. The computing device 700 may be any digital computing device configured to be suitable for implementing desired computing functions. In this embodiment, the computing device 700 includes an artificial intelligence (AI) accelerator 702 that corresponds to the CIM chip 400 implementing the memory array 200 shown in FIG. 3. The computing device 700 may further include a digital processor 704 and other types of digital memory 706. The computing device 700 may include any one or more of a display device 708, an audio output device 710, a communications circuit 712 for providing data communications over a data communications device 714 such as an antenna or data communication line, an electrical power supply 716 such as a battery or AC power supply, a location tracking device 718 such as a GPS device, an audio input device 720, and various other types of input devices 722 and/or output devices 724. A computing device in accordance with the present disclosure may have other configurations and is not limited to the example configuration shown in FIG. 10. The AI accelerator 702 may include a neural network 500 having n inputs (IN) 502 and m neurons 504, as exemplified in FIG. 11. The neural network 500 may have any number of layers of the neurons 504 as desired. The neural network 500 maps to the memory array 200 described in FIG. 3. FIG. 11 illustrates a fully connected (FC) layer. The FC layer has n neurons at layer i and m neurons at layer i+1, with n×m weights, corresponding to a 3T eDRAM array with m columns and n rows, as described in FIG. 6. Multiple 3T memory cells 114 might represent one weight because each eDRAM cell stores only one byte. If the actual data stored at each weight is larger than one byte, normally varying from 8 bytes to 64 bytes, then 8 to 64 memory cells 114 may be used to represent one weight.

As previously noted above, though the foregoing detailed description describes certain aspects of one or more particular embodiments of the invention, alternatives could be adopted by one skilled in the art. For example, the computer devices, integrated circuits, memory arrays, and memory cells, and their components could differ in appearance and construction from the embodiments described herein and shown in the drawings, functions of certain components of the computer devices, integrated circuits, memory arrays, and memory cells, and their components could be performed by components of different construction but capable of a similar (though not necessarily equivalent) function, and various materials could be used in the fabrication of the computer devices, integrated circuits, memory arrays, and memory cells, and their components and/or their components. As such, and again as was previously noted, it should be understood that the invention is not necessarily limited to any particular embodiment described herein or illustrated in the drawings.

1. A stacked three-transistors (3T) memory cell comprising:
a first thin-film-transistor (TFT);
a second TFT; and
a third TFT;
wherein the first TFT, second TFT, and third TFT are stacked in a plurality of layers in a three-dimensional (3D) configuration.

2. The stacked 3T memory cell of claim 1, wherein the second TFT is stacked on top of the first TFT.

3. The stacked 3T memory cell of claim 1, further comprising a capacitor stacked in the plurality of layers in the 3D configuration.

4. The stacked 3T memory cell of claim 3, wherein the capacitor is sandwiched between the first TFT and the second TFT.

5. The stacked 3T memory cell of claim 2, wherein the third TFT and the second TFT are disposed in the same layer of the plurality of layers.

6. The stacked 3T memory cell of claim 1, wherein the first TFT is in a first layer of the plurality of layers and the second TFT is in a second layer of the plurality of layers above the first layer.

7. The stacked 3T memory cell of claim 6, wherein the first TFT comprises a write access TFT, the second TFT comprises a storage TFT, and/or the third TFT comprises a read access TFT.

8. The stacked 3T memory cell of claim 1, wherein vias operatively connect electrodes of the first TFT, the second TFT, the third TFT, and the capacitor between the layers.

8. A compute-in-memory integrated circuit comprising:
a front-end-of-line (FEOL) layer comprising one or more logic circuits;
a back-end-of-line (BEOL) layer disposed on top of a top layer of the FEOL layer; and
a top-end-of-line (TOEL) layer disposed on a top layer of the BEOL layer;
wherein the TOEL layer comprises one or more stacked 3T memory cells operatively coupled with the top layer of the BEOL layer to form an electrical circuit therewith, one or more of the one or more stacked 3T memory cells comprising:
a first TFT;
a second TFT;
a third TFT; and
a capacitor;
wherein the first TFT, second TFT, third TFT, and capacitor are stacked in a plurality of layers in a three-dimensional (3D) configuration.

9. The compute-in-memory integrated circuit of claim 8, wherein the second TFT is stacked on top of the first TFT.

10. The compute-in-memory integrated circuit of claim 8, wherein the capacitor is sandwiched between the first TFT and the second TFT.

11. The compute-in-memory integrated circuit of claim 8, wherein the third TFT and the second TFT are disposed in the same layer of the plurality of layers.

12. The compute-in-memory integrated circuit of claim 8, further comprising at least one of an input driver, a read writeline driver, a write bitline driver, a write writeline driver, a multiplexer, a sense amplifier, an analog-to-digital converter, an adder tree, a shift-add unit, and a controller, operatively interconnected with each other and with the one or more stacked 3T memory cells for both data storage and computing.

13. The compute-in-memory integrated circuit of claim 8, wherein the compute-in-memory integrated circuit forms an embedded dynamic random-access memory (eDRAM) integrated circuit.

14. An embedded dynamic random-access memory (eDRAM) compute-in-memory device comprising an array of a plurality of the stacked 3T memory cells of claim 1, wherein each stacked 3T memory cell has a storage node that is in communication with one input signal and isolated from all other input signals in the memory array.

15. The eDRAM compute-in-memory device of claim 14, further comprising:
an input driver;
a read writeline driver;
a write writeline driver;
a write bitline driver; and
a read bitline driver;
wherein each of the stacked 3T memory cells is operatively coupled with each of the read writeline driver, the write writeline driver, the write bitline driver, the read bitline driver, and a capacitor plate line.

16. A computing device comprising:
the eDRAM compute-in-memory device of claim 15.

17. The computing device of claim 16, wherein the eDRAM compute-in-memory device comprises an artificial intelligence accelerator.

18. The computing device of claim 17, wherein the artificial intelligence accelerator comprises a neural network that maps to the array of stacked 3T memory cells.
